(19) United States
(12) Patent Application Publication
(10) Pub. No.: US 2008/0093055 A1
(43) Pub. Date: Apr. 24, 2008

(54) Heat-dissipating structure

(75) Inventors: Yih-Wei Tzeng, Taipei (TW); Win-Haw Chen, Taipei (TW); Chen Yueh Chang, Taipei (TW)

Correspondence Address: EDWARDS ANGELL PALMER & DODGE LLP, P.O. BOX 55874, BOSTON, MA, 02205, US

(73) Assignee: Inventec Corporation, Taipei (TW)

(21) Appl. No.: 11/586,460

(22) Filed: Oct. 24, 2006

(51) Int. Cl. H05K 7/20

(52) U.S. Cl. 165/104.26; 361/700; 165/80.3; 165/104.33

(57) ABSTRACT

This present invention provides a heat-dissipating element for dissipating heat generated by a heat source in an electronic apparatus. The heat-dissipating element includes a contacting portion, an extending portion having one end connected with the contacting portion, and a chamber connected with the contacting portion and the extending portion. The chamber is filled with a working fluid and comprises a plurality of capillary structures to which the working fluid is adhered, and one end of the contacting portion contacts with the heat source to absorb the heat generated from operation while the extending portion extends in a direction away from the heat source, such that heat generated from the heat source can be conducted into the extending portion and away from the heat source, thereby facilitating heat convection with the ambient cool air and enhancing heat-dissipation efficiency.

### BACKGROUND OF THE INVENTION

1. Field of the Invention

The present invention relates to heat dissipating elements, and more particularly, to a heat-dissipating element for use to dissipate and conduct heat away from a heat source in an electronic apparatuse.

2. Description of Related Art

As is well known, a semiconductor device used in a computing apparatus is required to conduct high-speed processing and that requires high voltage and thus generates considerable heat during high-speed processing, such devices and apparatuses must include a scheme for radiating the heat.

Heat sinks, also termed heat sinks or chillers, are used to conduct heat away from a heat source such as an electrical component directly or indirectly and into a passing fluid such as air. As such, there is provided a new technology for heat dissipation, characterized in that a chamber is formed in a heat sink to be filled with a plurality of capillary structures and a working fluid therein, such that the phase-changing circulation of vapor and condensation of the working fluid is generated in the chamber for absorbing heat generated from a heat source.

Referring to FIG. 1, a chamber 10 is formed in a heat sink 1, which is formed in a flat-board shape and comprises a condenser surface 11 and a vapor surface 12. The condenser surface 11 is provided with heat-dissipating fins 13. A heat source 14, such as a CPU, is disposed on the vapor surface 12. The chamber 10 is filled with a working fluid of high expansion coefficient, and comprises a plurality of capillary structures 15 disposed on two opposed inner sides of the chamber 10, for absorbing the working fluid and generating a capillarity phenomenon.

When the heat source 14 generates heat, the working fluid filled into the chamber 10 of the heat sink 1 is heated and then vaporized into gas via the vapor surface 12, such that the working fluid around the condenser surface 11 is pushed forward to be absorbed by the capillary structures 15 and is conducted toward the heated vapor surface 12, while the working fluid that has become gas flows in an opposite direction toward the condenser surface 11 so as to be condensed to form liquid, which is then absorbed by the capillary structures 15 and flows through the vapor surface 12, thereby repeating the foregoing circulation to dispel the heat.

However, the vapor surface 12 is closely adjacent to the condenser surface 12 due to the flat-board shape of heat sink 1, such a structure limitation results in a slower speed of condensing steam on the condenser surface 11 into liquid than the speed of vaporized liquid on the vapor surface 12 into steam, adversely affecting the efficiency of heat-dissipation.

Further, although a plurality of heat-dissipating fins 13 can be deployed on the periphery of the condenser surface 12 to extend and enlarge the heat-dissipating area, the deployment of more fins necessitates increased cost for precision molds for making the fins 13.

Therefore, it is desired to provide a novel mechanism and technique that improves on the drawbacks of prior techniques for heat dissipation.

### SUMMARY OF THE INVENTION

The present invention has been achieved in view of the foregoing problems and its object is to provide a heat-dissipating structure that facilitates and ensures a favorable degree of heat dissipation.

Another object of the present invention is to provide a heat-dissipating structure that enables the cost of fabrication to be reduced.

According to one aspect of the present invention, there is provided a heat-dissipating structure for dispelling heat generated in an electronic apparatus, the heat-dissipating structure comprising: a contacting portion and one side thereof contacting with the heat source for absorbing heat generated from operating; an extending portion connecting with the contacting portion and extending from a direction away from the heat source; and a chamber connecting with the contacting portion and the extending portion, wherein the chamber is filled with a working fluid and a plurality of capillary structures to which the working fluid is adhered, thereby using the phase-changing circulation of the working fluid to absorb and conduct the heat to the extending portion and away from the heat source to facilitate heat convection with the ambient cool air, thus enhancing the efficiency of heat-dissipation.

In one preferred embodiment, the extending portion is disposed at two opposite ends of the contacting portion, thereby using the U-shaped structure to conduct heat away from the central portion by spreading it toward two sides to prevent a phenomenon of heat-accumulation at the central portion.

In contrast to the prior technique in which a heat sink of a single flat-board shape is known to have problems in heat-dissipation, the heat-dissipating structure of the invention features using an extending portion to conduct heat way from the heat source for heat-convection with ambient cool air, thereby ensuring an effective heat dissipation.

Further, as the heat sink of the present invention has an extending portion that extends from two opposite ends of the contacting portion thereof, the inner surface corresponding to the extending portion is much larger than the condenser surface of the known heat sink, thereby significantly increasing the speed of condensing steam into liquid that promotes gas circulation in the chamber and the efficiency of heat-dissipation as a result.

Also, compared to the prior technique in which dense deployment of heat-dissipating fins is required in order to extend the heat-dissipating area, the heat-dissipating structure of the invention has an enlarged heat-dissipating area for facilitating heat dissipation. In addition, the outside of the heat-dissipating structure can be further provided with heat-dissipating fins to increase the area, eliminating the need to closely dispose the fins and the burden to fabricate such fins that in turn can reduce the manufacturing cost as a result. More preferably, the outer surface of the extending portion can be made with corrugated ripples to realize a desired size of heat-dissipating area.

Accordingly, the present invention offers advantages over prior techniques and thus possesses high industrial applicability.

Note that this summary of the invention does not necessarily describe all necessary features so that the invention may also be a sub-combination of these described features.

### BRIEF DESCRIPTION OF DRAWINGS

The heat-dissipating structure of the present invention can be fully understood by reading the following detailed description of the preferred embodiments, with reference made to the accompanying drawings, wherein:

FIG. 1 (PRIOR ART) is a perspective view showing a conventional heat sink in the prior art;

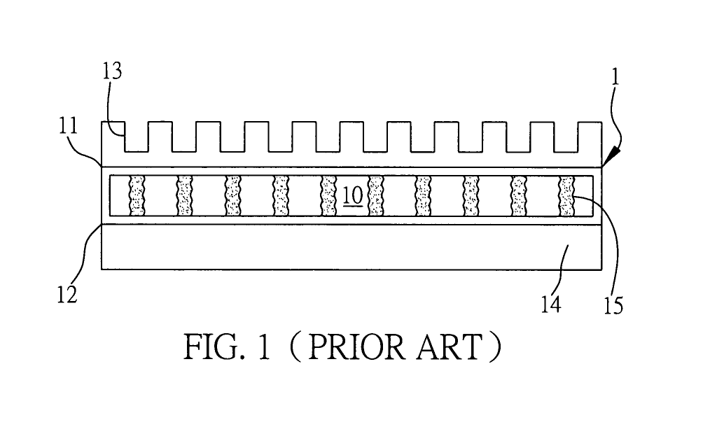

FIG. 2 is a perspective view showing a first preferred embodiment of the heat-dissipating structure in accordance with the present invention;

FIG. 3 is a perspective view showing a second preferred embodiment of the heat-dissipating structure in accordance with the present invention;

FIG. 4 is a perspective view showing a third preferred embodiment of the heat-dissipating structure in accordance with the present invention; and

FIG. 5 is a perspective view showing a fourth preferred embodiment of the heat-dissipating structure in accordance with the present invention.

### DETAILED DESCRIPTION OF PREFERRED EMBODIMENT

The present invention is described in the following so that one skilled in the pertinent art can easily understand other advantages and effects of the present invention. The present invention may also be implemented and applied according to other embodiments, and the details may be modified based on different views and applications without departing from the spirit of the invention.

### First Preferred Embodiment

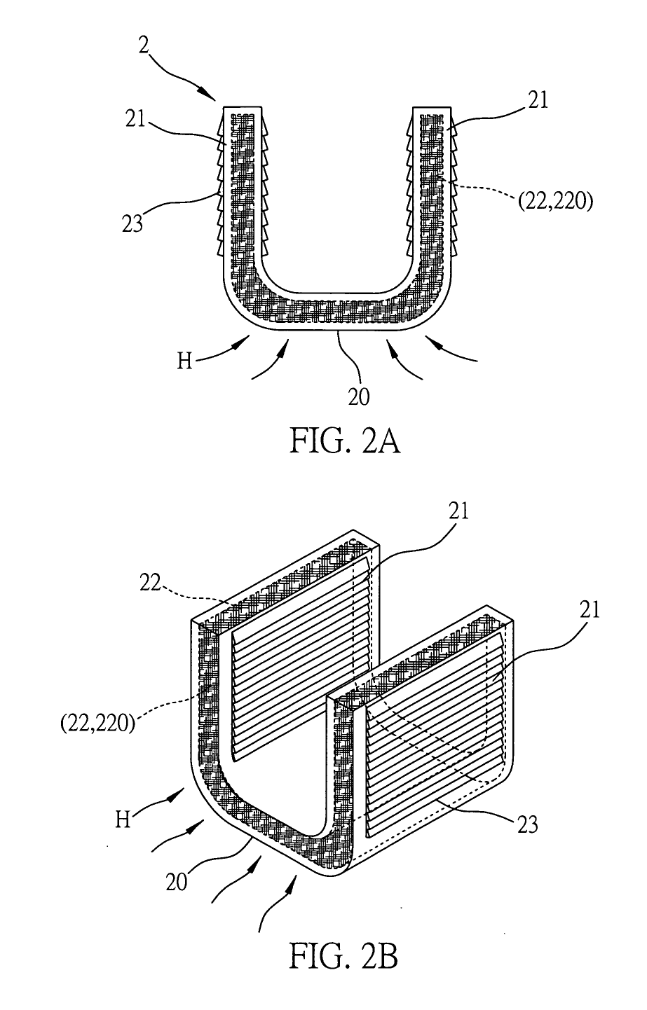

In FIGS. 2A and 2B, a heat-dissipating structure 2 of the present invention is adapted to dissipate and conduct heat H away from a heat source (not shown). The heat source is, for example, a CPU or a semiconductor chip and the like, and generates heat when being electrically conducted for operation. The heat-dissipating structure 2 according to the present invention comprises a contacting portion 20 having one flat side contacted with the heat source and absorbing heat H generated by the heat source, an extending portion 21 integrally formed to bend and connect with two ends of the contacting portion 20 and extending in a direction away from the heat source, and a chamber 22 connected with the contacting portion 20 and the extending portion 21. The chamber 22 is filled with a working fluid and comprises a plurality of capillary structures 220 to which the working fluid is adhered, thereby using a phase-changing circulation of the working fluid to absorb heat generated from the heat source, and further conducting heat to the extending portion 21 away from the heat source to facilitate heat convection with the ambient cool air, thus enhancing the efficiency of heat-dissipation.

Note that in this embodiment, the extending portion 21, constructed to bend at two ends of the contacting portion, is illustrative but not restrictive to this choice and the extending portion can be posited at any arbitrary position on the contacting portion 20, so long as the heat generated can be conducted away from the heat source. The configuration of the extending portion 21 bending at two ends of the contacting portion 20 allows the heat-dissipating structure 2 to have a U-shaped structure, thereby conducting heat to the two ends thereof to prevent buildup of heat at the central region thereof.

In contrast to the conventional heat sink of a single flat-board shape that is known to have an unsatisfied degree of heat-dissipation, the heat-dissipating structure 2 of the invention features using an extending portion 21 to conduct heat away from the heat source for heat-convection with ambient cool air, thereby ensuring an effective heat dissipation.

Further, the heat-dissipating structure 2 of the present invention has an extending portion 21 constructed to extend from two opposite ends of the contacting portion 20, therefore, the inner surface corresponding to the extending portion 21 is much larger than the condenser surface of the conventional heat sinks, thereby significantly increasing the speed of condensing steam into liquid and that promotes gas circulation in the chamber and the efficiency of heat-dissipation as a result.

The contacting portion 20 is a metallic contacting portion and the extending portion 21 is integrally formed to bend on the contacting portion 20, thus making the heat-dissipating structure 2 a U-shaped structure. In addition, the outer surface of the extending portion 21 can be provided with a plurality of heat-dissipating fins 23 to further expand the area for heat dissipation, and such fins 23 can be loosely deployed since the use of the extending portion 21 in the invention has significantly enlarged the heat-dissipating area that makes dense deployment of fins 23 unnecessary, reducing the cost for fabricating the fins 23 as a result. More preferably, the outer surface of the extending portion can be made with corrugated ripples to realize a desired size of heat-dissipating area.

### Second Preferred Embodiment

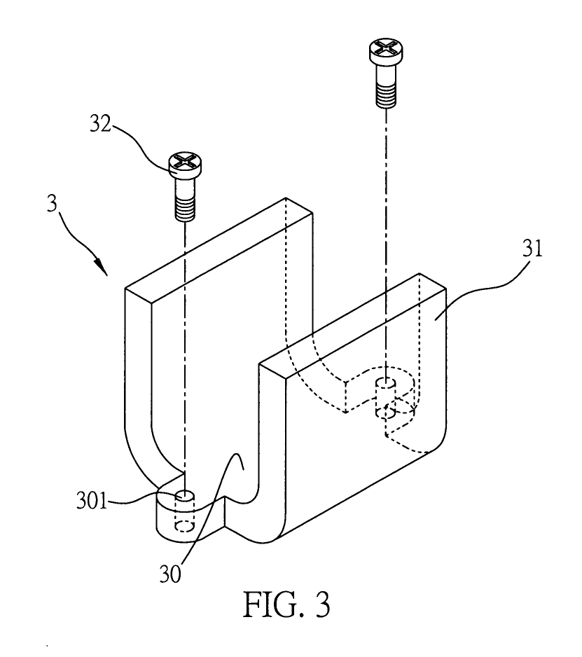

Referring to FIG. 3, a contacting portion 30 of a heat-dissipating structure 3 is provided with screw holes 301 on two sides thereof for coupling with screw bolts 32 to fasten the heat-dissipating structure 3 onto a heat source (not shown).

The connecting relation between the extending portion 31 and the contacting portion 30 and the effect of the extending portion 31 are substantially the same as that of the foregoing embodiment, and thus will not be further described herein.

### Third Preferred Embodiment

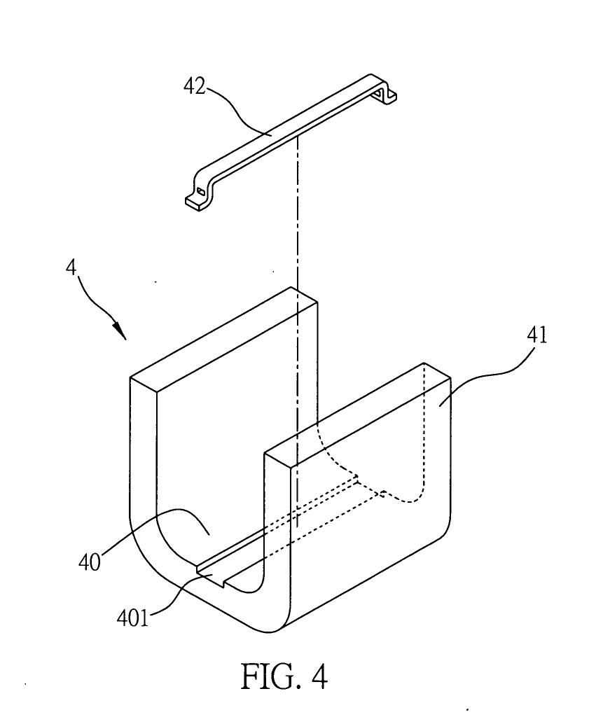

Referring to FIG. 4, a contacting portion 40 of a heat-dissipating structure 4 is provided with a groove 401 on a top surface thereof for coupling with a mating elastic piece 42 to fasten the heat-dissipating structure 4 onto a heat source (not shown).

The connecting relation between the extending portion 41 and the contacting portion 40 and the effect of the extending portion 41 are substantially identical to that of the foregoing embodiment, and thus will not be further described herein.

### Fourth Preferred Embodiment

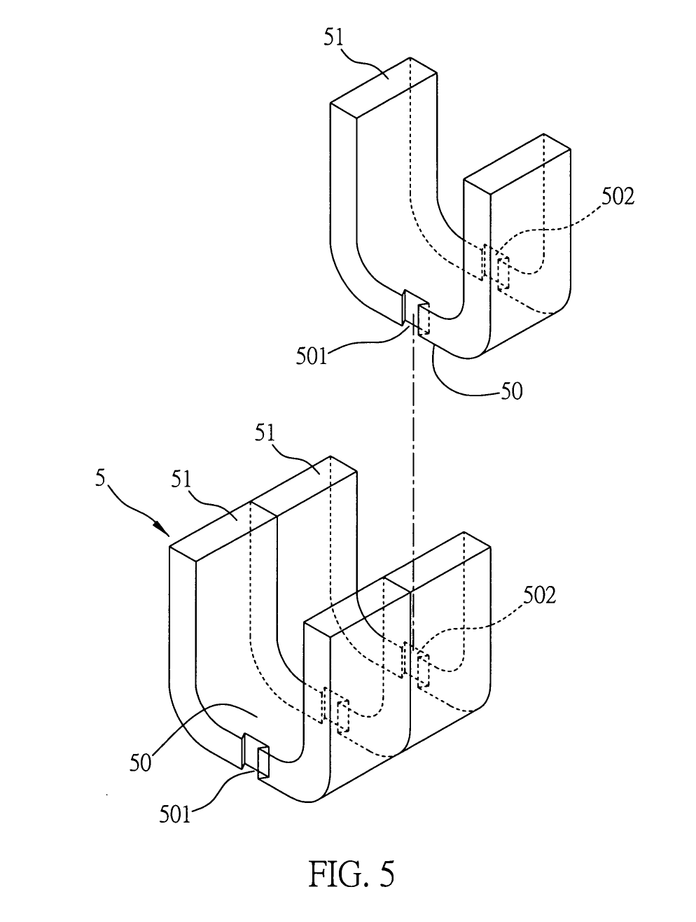

Referring to FIG. 5, a contacting portion 50 of a heat-dissipating structure 5 is provided with a pair of corresponding assembling portions 501, 502 on two opposite sides thereof, allowing the heat-dissipating structure 5 to be assembled with another heat-dissipating structure 5 for adjustment of size to comply with the size of the heat source (not shown). The pair of the assembling portion 501, 502 are a tail groove and a tail block respectively, or other equivalent structures.

Note that this embodiment is variable and can be derived from any one of the embodiments described above. The connecting relation between the extending portion 51 and the contacting portion 50 and the effect of the extending portion 51 are substantially the same as that of the foregoing embodiment, and thus will not be further described herein.

Accordingly, the present invention offers advantages over prior techniques and thus has high industrial applicability.

The aforementioned examples are only exemplary preferred embodiments of the present invention. The scope of the claims as stated below should be accorded the broadest interpretation so as to encompass various modifications and similar arrangements made to the herein described invention that fall within the spirit of the basic principles and technology of the present invention.

What is claimed is:

1. A heat-dissipating structure adapted to dissipate heat generated by a heat source, the heat-dissipating structure comprising:
a contacting portion having a contacting side contacted with the heat source for absorbing the heat;
an extending portion connected with the contacting portion and extended in a direction away from the heat source; and
a chamber connected with the contacting portion and the extending portion, wherein the chamber is filled with a working fluid and comprises a plurality of capillary structures to which the working fluid is adhered, thereby using a phase-changing circulation of the working fluid to absorb and conduct the heat to the extending portion and away from the heat source to facilitate heat convection with ambient cool air, thus enhancing heat-dissipation efficiency.

2. The heat-dissipating structure of claim 1, wherein the contacting portion is a metallic contacting portion, and the extending portion is integrally formed to extend from the contacting portion.

3. The heat-dissipating structure of claim 1, wherein the extending portion is integrally formed to bend at two opposite ends of the contacting portion and thus forms a U-shaped structure.

4. The heat-dissipating structure of claim 1, wherein two opposite ends of the contacting portion are provided with screw holes to be connected with corresponding screw bolts formed thereon, thereby fastening the heat-dissipating structure onto the heat source.

5. The heat-dissipating structure of claim 1, wherein the contacting side of the contacting portion is in a flat-board shape.

6. The heat-dissipating structure of claim 1, wherein the contacting portion has a groove formed on a top surface thereof to be coupled with a mating elastic piece, thereby fastening the heat-dissipating structure onto the heat source.

7. The heat-dissipating structure of claim 1 further comprises a heat-dissipating fin formed on an outer surface of the extending portion.

8. The heat-dissipating structure of claim 1, wherein two opposite ends of the contacting portion are provided with two corresponding assembling portions, thereby assembling the heat-dissipating structure with another heat-dissipating structure by the coupling of the assembling portions.

9. The heat-dissipating structure of claim 8, wherein the assembling portions formed on two sides of the contacting portion are respectively a tail block and a tail groove.
